(19) United States
(12) Patent Application Publication
(10) Pub. No.: US 2016/0370411 A1
(43) Pub. Date: Dec. 22, 2016

(54) CHARGE TRANSFER MEASUREMENT TECHNIQUES

(71) Applicant: AZOTEQ (PTY) LTD, Paarl (ZA)

(72) Inventors: Frederick Johannes BRUWER, Paarl (ZA); Dieter Sydney-Charles MELLET, Paarl (ZA); Douw Gerbrand VAN DER MERWE, Paarl (ZA); Daniel Barend RADEMEYER, Paarl (ZA); Jean VILJOEN, Paarl (ZA)

(73) Assignee: AZOTEQ (PTY) LTD, Paarl (ZA)

(21) Appl. No.: 15/122,174

(22) PCT Filed: Feb. 27, 2015
(86) PCT No.: PCT/ZA2015/000011

§ 371 Date: Aug. 28, 2016

(30) Foreign Application Priority Data
Feb. 28, 2014 (ZA) 2014/01531
Aug. 18, 2014 (ZA) 2014/06036
Nov. 18, 2014 (ZA) 2014/08445

(51) Int. Cl. G01R 27/26

(52) U.S. Cl. CPC G01R 27/2605

(57) ABSTRACT

A charge transfer measurement system which includes a clock, a capacitor, current mirrors and a counter wherein a signal current which is based on magnetic field, incident light or radiation, acceleration or an external inductance is transferred to the capacitor with the counter recording a count value and wherein the measurement is stopped after a predetermined time or when a voltage on the capacitor exceeds a reference value.

### BACKGROUND OF THE INVENTION

### Noise:

There are many applications where it is required to measure the response of a system when the system is excited by a specific event or stimulus. The system responds to the stimulus with noise added by the system to the response: it can be random Gaussian noise or a specific interferer such as hum or a combination of many noise sources. A transducer is used to convert the response (including noise) to an electrical signal which can be measured with an electronic circuit or measurement system. Most often the transducer will add additional noise to the response as well. (Refer to FIG. 1, a block diagram of a general measurement system.)

An example of such a system is the use of a pyroelectric detector to determine human intrusion into a specific area The pyroelectric detector measures the temperature of the environment responding to infrared radiation and generates a signal proportional to the average background temperature. When a person moves into the area, the increase in temperature due to the human body results in a change in the signal. The detector converts the infrared radiation to a current proportional to the temperature.

To detect if a human entered the area it is necessary to measure a change in the output current of the detector. Over time the background temperature and other parameters change, the measurement system must be able to accommodate this and be able to track the environmental conditions

### Noise Reduction:

To improve the signal to noise ratio multiple measurements can be made and an average value obtained to reduce the effect of random Gaussian noise. If it is assumed that the signal and noise are uncorrected and the signal is constant during the measurement: the signal to noise ratio [S/N]n after n measurements will be:

[S/N]n−√n S/σ=√n [S/N]i

With c the standard deviation in the spread of a single measurement with signal to noise ratio [S/N]i. In the ideal case the signal to noise ratio increase with the square root of the number of measurements averaged.

There are many ways to implement a measurement system to make multiple measurements and obtain an average value. Charge transfer techniques allow for simple analog, cost effective methods to implement this without using any classic analog to digital converters.

### Current Mirrors:

The use of current mirror structures is well documented in the prior art. A current mirror consists of 2 devices or more—see FIG. 5. The current flowing through the input impedance 2 is replicated to the output port. By using multiple identical devices the output current can be scaled if n input devices and m output devices are used the output current becomes:

I_{OUT}=(m/n)*I_{IN}

With the use of switches to switch devices in or out an adjustable ratio can be implemented. There are many ways of implementing a current mirror, two examples commonly used are with bipolar transistors or field effect transistors.

### Passive Infra-red Sensors:

Passive Infra-red (PIR) sensors are used for many applications such as intruder alarms, switches etc. The sensor consists of pyroelectric material. The pyroelectric detector measures the temperature of the environment responding to infrared radiation and generates a signal proportional to the average background temperature. Often the pyroelectric material is coupled to the gate of a junction field effect transistor. Infrared radiation changes the output voltage from the pyroelectric material which in turn changes the transconductance of the JFET. The drain of the JFET is coupled to the supply voltage and the source is coupled to the input of the measurement system. The infrared radiation controls the current through the JFET.

In traditional PIR sensors, two sensors with similar characteristics are often used in a back-to-back pairs with their polarities in opposition. This allows automatic compensation for drifts in the output of said sensors. For example, if the one sensor output drifts in one direction due to a change in ambient temperature, the output of the other sensor in the pair should drift in the opposite direction, thereby automatically compensating for the first drift. The drawback of this approach is of course that two sensors need to be used, and they need to have matching characteristics.

### Flame Detection:

Flame detection is known in the prior art, based on the frequency analysis of light waves emitted by said flames. For example, this is achieved by searching for a certain flicker frequency in light waves emitted by the flames.

### Smoke Detector:

According to the prior art, a smoke detector may be implemented using a light emitting diode as an emitter and a photodiode or phctotransistor as receiver. Most sensors mount the emitter and receiver at an angle inside a chamber so that no light impinges on the receiver when there is no smoke. When smoke gets inside the chamber it reflects light to the receiver, triggering an alarm.

### Impedance or Wheatstone Bridges:

Impedance bridges, for example a resistive Wheatstone bridge as shown in FIG. 7 are widely used as a measuring instrument for various physical signals as well as a modelling instrument for various transducers. These include but are not limited to pressure-force, displacement, Hall effect etc. Traditionally, such a bridge is applied in a ratio-metric mode in that the measured entity is the ratio between the supply voltage V-bias of the bridge and the measured output voltage represented by V1−V2. This typically implies having to deal with large offsets as well as large dynamic ranges. Dealing with these drawbacks requires many special techniques for example, to reduce the offset, rotational switching of the bias voltage and measured signal around the bridge, or a chopper stabilized op-amp are implemented. Furthermore, increasing the desired signal is normally directly proportional to the biasing voltage and thus reducing the large dynamic range may imply incorporating dividing techniques such as resistor dividers. These techniques not only increase power dissipation but also introduce new noise sources and complexity and the need for accurate referencing which typically requires calibration in the production phase.

The use of inductance related measurements to monitor the movement of targets is known in the prior art. In U.S. 2014/0247040 by Reitsma et at a position detecting system is taught which measures the increase/decrease in the power less for a time varying magnitude field due to an increase/decrease in eddy currents as a conductive target moves closer/further from a coil, where the coil generates said time varying field. Alternatively the quality factor of a tank circuit is measured, where a coil which faces a conductive target provides the inductive reactance for said tank, and use is made of a negative impedance circuit. In U.S. 2014/0247090 by Reitsma et al resonant impedance sensing based on generation of a controlled negative impedance to monitor a target is taught.

### SUMMARY OF THE INVENTION

Most often when system measurements are to be made, all the signals are in terms of voltages. According to the present invention, using currents as signals instead of voltages, charge transfer techniques may make it possible to implement a measurement system which is relatively simple while having a large dynamic range.

The present invention teaches that a charge transfer measurement system may be implemented as follows to obtain an average value from multiple measurements. A sampler circuit terminates the output from a sensor in an appropriate impedance, and wherein an accumulation capacitor C_{S} is in a discharged state initially. A clock source controls said sampler circuit. Every time the clock goes high a sample (charge=Q_{O}) of the input current Io from the sensor is transferred to the accumulation capacitor. When the voltage on the accumulation capacitor reaches a reference voltage, V_{REF}, a comparator trips and stops a counter. The average current I_{O}_{_}_{AVE} and average charge Q_{AVE} sampled by the sampler circuit with each transfer is given by:

Q_{AVE}=(C_{S}*V_{REF})/Count

I_{O}_{_}_{AVE}=2*Q_{AVE}/T

With T the clock period and Count the number of transfers when the comparator tripped

### Digital Filter:

A further enhancement of the charge transfer measurement system is to make measurements on a regular basis and feed the value of the average charge Q_{AVE} into a digital filter which then calculates a long term average Q_{LTA}. This filter allows the system to track slow environmental changes like temperature drift, component aging and humidity and compensate for it. The signal change when the sensor detects a stimulus is:

Q_{A}=Q_{O}−Q_{LTA}

If a fixed limit was used instead of Q_{LTA} the system would be prone to false detections, or alternatively a big change in Q_{O} would be required to eliminate false detections. This is not always possible.

### Background Compensation

When trying to detect a change in a parameter it is easier to measure Q_{A} when Q_{A} and Q_{O} are more or less of the same magnitude. An indication of the ease of measurement is the detection sensitivity:

D=Q_{A}/Q_{O}

The larger the value of the detection sensitivity D, the easier it is to detect a change in the parameter to be measured.

To improve the detection sensitivity it is often better to subtract a fixed background value from Q_{O}. For example when using a photodiode there is often a current flowing due to background light. Subtracting this background current from the measured current in the sampler circuit gives better detection sensitivity. With each charge transfer an amount of charge Q_{S} is subtracted from the incoming charge Q_{O}. With background compensation the output from the sampler circuit becomes:

Q_{P}=Q_{O}−Q_{B}

With Q_{P} the charge value adjusted for the background current, and Q_{B} the charge proportional to the background current I_{B}.

In this case, with background compensation, the value of Q_{P} is fed to the digital filter to calculate a long term average, Q_{P}_{_}_{LTA} which is then used to determine if there is a change in the incoming charge

Q_{AP}=Q_{P}−Q_{P}_{LTA}

The digital filter fulfils its function to allow the system to track slow environmental changes like temperature drift; component aging and humidity and compensate for it. however if it is found that the long term average drifts considerably the system can also determine a new value for Q_{B}; by doing this a better detection sensitivity can be maintained.

The detection sensitivity with background compensation is now:

D_{P=}Q_{AP}/Q_{P}>>D=Q_{P}/Q_{O}

### Sampler Circuit

According to the present invention, a sampler circuit, as used by the charge transfer measurement system, may be realised as follows. Current from the sensor being monitored is terminated by an impedance Z, which results in a sensor or input current I_{Z}. Background current I_{S} is subtracted from the sensor current, with the difference current (I_{Z}−I_{S}) entered into a gain block with gain G. resulting in an output current G*(I_{Z}−I_{B}). The system gain G can be larger than or less than one depending on the application. For certain applications it may be better to subtract the background current after the gain block, as long as the gain block has sufficient dynamic range to handle the uncompensated input current.

### Current Mirror Implementation of a Charge Transfer Measurement System:

There are many different ways to implement a charge transfer measurement system. One of the most effective methods is the use of current mirrors, as taught by the present invention. The main components of such a system are an adjustable gain block, a background compensation block, a charge integrator and peripheral electronics. The gain block may be implemented with two adjustable current mirrors, allowing it to adjust current gain up or down depending on the requirement of the specific application. The gain block may add a packet of charge to the charge integrator with each clock pulse.

The background compensation block may be implemented in many ways. One implementation method comprises an adjustable current mirror with an adjustable current source on the input side, and wherein a packet of charge is subtracted with each clock pulse from the charge integrator. Another implementation method comprises a bank of switchable capacitors with a current mirror. During ore half of the clock pulse the capacitors are charged up to the supply voltage, during the other half of the clock pulse the capacitors are discharged through the current mirror removing a packet of charge from the charge integrator. Switching capacitors in or out may also be used to allow the system to adjust the amount of charge removed.

### Measurement Applications:

According to the present invention, a charge transfer measurement system as described may be used in a multitude of applications, of which a few examples are listed below:

### Touch Sensors—Self—Capacitance Based:

A self-capacitance touch or proximity sensor may be implemented by connecting a single electrode to the input port of a charge transfer measurement system as described The electrode is charged to the supply voltage during one half of the clock cycle, during the second half the electrode is discharged into the input port. The background compensation is adjusted to cancel unwanted parasitic capacitance at the measurement electrode increasing the detection sensitivity. The digital filter allows the system to continuously adjust the long term average to compensate for environmental factors.

### Touch Sensors—Mutual—Capacitance:

A mutual-capacitance touch or proximity sensor can be implemented using two electrodes. One electrode is coupled directly to the input port. A second electrode in proximity to the first electrode is charged up during one half of the clock cycle. The capacitance between the two electrodes is discharged during the second half of the clock cycle into the input port of the measurement system The background compensation is used to adjust the detection sensitivity of the system. The digital filter allows the system to continuously adjust the long term average to compensate for environmental factors.

### Passive Infrared Sensors.

PIR sensor current may be measured by the charge transfer measurement system of the present invention. The background compensation may be used to cancel out background current while the digital filter may allow the system to continuously adjust the long term average to compensate for environmental factors.

According to the present invention, a single PIR sensor may be monitored in the disclosed manner using a charge transfer measurement circuit, and compensation for signal output drifts may be performed in the digital domain through comparison with a long term average or reference value. That is, according to the teachings of the present invention, it need not be necessary to use two PIR sensors in a back-to-back pair to compensate for longer term drifts such as temperature drifts, but it may be done with a single PIR sensor and a charge transfer measurement system as disclosed.

Furthermore, the present invention teaches that it may be possible to realize a single PIR sensor based measurement circuit to give an accurate estimate of the absolute ambient temperature. As disclosed, a PIR sensor may be monitored with a charge transfer based measurement circuit. During manufacture, absolute ambient temperature measurements are used to calibrate the combination of a charge transfer measurement circuit and a specific PIR sensor. That is, specific values of absolute ambient temperature are tied to specific output values of the combination of the specific PIR sensor and said charge transfer measurement circuit, taking into account any settings of the circuit. The calibrated PIR sensor and charge transfer measurement circuit combination may thereafter be used to measure absolute ambient temperature. In addition, the aforementioned drift compensation for a single PIR sensor may be used to compensate for thermal, or other, drifts of said calibrated PIR sensor and charge transfer circuit measurement circuit combination.

A PIR sensor and charge transfer measurement circuit which can provide an accurate estimate of the absolute ambient temperature may be used in a fire alarm, as an example, according to the present invention, if the ambient temperature goes above a certain threshold, for example 80 degrees Celsius, the fire alarm may deduce that a fire has started, and give audible or visual warning.

According to the present invention, it may also be possible to realize a PIR sensor and charge transfer measurement circuit combination with the ability to recognize flames. With a PIR sensor connected to a charge transfer measurement circuit, the resulting counts of charge transfers provide measurement data in the digital domain. Said counts data may be used to perform digital frequency analysis, for example performing Fast Fourier Transforms, and the result may be used to detect flames. This may also be used in a fire alarm system, as an example.

Further, the present invention teaches that a three terminal PIR sensor device, (typically comprising dual sensors connected to a FET and enclosed in a metal housing with a translucent lens), may be connected to a charge transfer based projected capacitive measurement device. Using current mirror and capacitive removal methods, as disclosed in U.S. Pat. No. 8,395,395 and U.S. Pat. No. 8,659,306 of the present applicant, to adjust offsets and gain, signal deviation may be measured with high clarity when objects with different back body radiation temperatures project radiation onto the PIR sensor.

Using digital filtering techniques and averaging, it is very easy to detect motion and set limits for the required signal strengths and frequency of occurrence to register a motion event. Because it is so simple and cost effective to add another PIR sensor to a charge transfer based projected (or self) capacitance measurement device, two sensors may be used with a long distance and a short distance lens (Fresnell) to help distinguish size and shape.

### Smoke Detector:

According to the present invention, the charge transfer measurement system as discussed may be used to measure the current from a photo receiver in a smoke detector which have the emitter and receiver mounted at an angle relative to another. Background compensation as disclosed may be used to improve sensitivity, and the digital filter to compensate for environmental factors such as light leaking into the chamber

A more direct measurement is to measure the smoke obscuration by lining up the light emitting diode and the receiver in a straight line. When smoke enters the area between the emitter and receiver it reduces the intensity of the light on the receiver, triggering an alarm, in this case the use of a charge transfer measurement system may cancel the current from the sensor when no smoke is present using the background compensation, allowing the system to measure the change in current when any smoke obscures the path between the emitter and receiver. The digital filter may be used to compensate for environmental factors such as temperature dependence of the emitter and receiver

### Voltage, Current and Capacitance:

Absolute and relative measurements of voltage and current may be made with a charge transfer measurement system as described For a voltage measurement, a high value resistor may be used to convert it to a current, which is then measured by the charge transfer system. For absolute measurements a reference calibration may need to be performed.

### Temperature:

Temperature may be measured by using the current through a diode. Relative temperature measurements and absolute measurements may be made if the system is calibrated.

Sensors using a Wheatstone Bridge as a Balanced Sensor or Model:

Using the proposed charge transfer measurement system with a Wheatstone bridge may relax the large dynamic range requirements constraints of prior art applications, and also eliminate the need for accurate referencing due to the highly adaptive nature of said system. Furthermore, the background compensation may be used to eliminate the inherent offset, thereby significantly amplifying the signal of interest as well as improving the overall signal-to-noise ratio. The signal may then be post processed using one or all of the methods described.

A further improvement of Wheatstone bridge model applications is to combine pro-amplification of the signal, which can be either a current or a voltage being measured. The charge transfer measurement system may then be the load to the pre-amplification circuit. That is, the output of said pre-amplification circuit is used as input to the charge transfer measurement system as disclosed. The background compensation becomes a major advantage to eliminate the offset, allowing only the signal of interest to be measured.

A Hall effect transducer in current mode (it may also be voltage mode) is an exemplary application that may be modelled using a Wheatstone bridge. Currents from the Hall plate are typically directly proportional to the magnetic field B and result from the Lorentz force acting upon the bias current that flows through the bridge. This current signal is amplified with a gain A and is then measured and processed by the charge transfer measurement system as described above. In other words, the outputs of the two amplifiers with gain A are used as inputs to the charge transfer measurement system as disclosed.

### Magnetic Field Rotation Measurement.

According to the present invention, Hall effect transducers or sensors may be combined with a charge transfer measurement circuit in an Application Specific Integrated Circuit (ASIC), and used to measure rotation of magnetic field sources, for example of a permanent magnet, it is envisaged that said ASIC may contain more than one Hall sensor, for example two sensors, positioned at different locations within the ASIC package. If a magnetic field incident on the ASIC rotates, the output of the various Hall sensors should change in a similar manner, but with a time difference, or lag between the respective changes. From the amount of lag, rotation speed may be deduced, using charge transfer measurements of said Hall effect sensor outputs, or of associated amplification circuits, according the present invention. Or, in another embodiment, if a plurality of Hall sensors within said ASIC is oriented at 90 degrees to each other, it may be possible to measure static rotation of magnetic field sources with charge transfer measurements as disclosed and said ASIC.

### Optical Sensor Measurement:

The measurement of light, ambient light, changes in light levels etc. with a charge transfer technique as disclosed may be very attractive and offer low cost, high resolution, wide dynamic range and low current consumption. Taking the implementation of current mirrors for scaling charge and parasitic capacitance cancellation techniques into account (refer to U.S. Pat. No. 8,395,395 and U.S. Pat. No. 8,859,308, which share inventors with the present application), a low cost, standard CMOS IC may be designed to offer auto-calibration. tuning and enough accuracy to offer reliable ambient light measurements as well as measurements for motion detection using standard PIR sensors, as discussed previously.

For ambient light detection a regular charge transfer measurement IC, such as used for self (surface) capacitive sensing, for example an Azoteq 1QS127, may be used by connecting it to a simple photodiode. The photodiode active spectrum should be chosen to be compatible with the application. The photodiode is modelled in its reverse biased position as a capacitor (the junction capacitor) and a parallel resistor that varies according to the light intensity incident on it. A parameter that is important is the capacitance of the reverse biased photodiode. In relation to the size and variance of the resistor. The internal pn-junction capacitance may be supplemented with an external capacitor in order to achieve the appropriate values.

As is known in the art, a charge transfer measurement system is subject to timing, such as the charge transfer frequency (number of charge transfer cycles completed per second), charge period (up), discharge period (pass) and a dead period between up and pass. The RC time constant formed by the internal junction capacitance (along with any external capacitance) and the light dependent resistor may affect the charge transfer measurement system implementation, and may place an upper limit on the charge transfer frequency used.

In principle when the light sensor is in a dark environment, the resistor has a high value and hence the capacitor gets charged during the charge or up phase of the cycle and then discharges into the measurement IC during the pass cycle. The values may be chosen such that little charge gets shunted to ground through the variable resistor. This results in a charge transfer measurement that may be calibrated in terms of light or ambient light. Obviously if the resistor changed in another direction i.e. low when dark etc., it is merely in the interpretation of Use measurement. In other words, the present invention is not just limited to embodiments where the resistor has a high value in a dark environment and a low value when a large amount of light is incident on said photo diode.

Please note that although the implementation is described using the Azotea IQS127 integrated circuit type implementation, the photodiode may be used along with other capacitive measurement and charge transfer engines as well.

The disclosure above provides a very flexible and light measurement implementation with very low power consumption and without a need for op-amps or other analogue circuitry. The cost of a single photodiode is very low. Using for example two photo diodes, such as one for infra-red and one for visible light, one can make a more accurate calculation of the ambient natural light level.

### Multi-Sensor Integrated Circuits:

According to the present invention, a single integrated solution may interface with a capacitive sensing electrode to measure user proximity, as well as with a photodiode to measure ambient light and have an embedded Hall sensor to measure magnetic field strength, and wherein all sensor inputs are measured with a charge transfer measurement system as disclosed. The Hall effect sensor may be expanded to measure three axes that are useful for orientation detection. According to the present invention, such an integrated solution may be used in a tablet computer, or in a Smart Phone. For example, the Hall sensor may be used to detect the opening or closure of a cover for said tablet or phone.

Or, in another embodiment, the above single integrated solution may allow a user to control functions on a tablet or phone even when the cover for said tablet or phone is closed. For example, with the cover closed, and using measurement of an integrated Hall sensor as disclosed, a user may rotate a magnet contained by said cover, which then instructs the device to enter a low power sleep mode, but still maintain email download on a regular basis Or rotation of said magnet in said cover may be used to enter or exit the phone into or from a silent mode. Or manipulation of said magnet or magnets contained by the cover may be used as a security feature, wherein a specific sequence of manipulation is required before a cover may be opened without an alarm (audible, visual or other) being raised. Or it may be used as a personal protection feature, where a specific manipulation of said magnet or magnets sends an emergency message to a pre-selected recipient, or where GPS tracking is activated, with coordinates communicated automatically to said recipient, or to the police. Or manipulation of said magnets may be used to unobtrusively start a sound recording function by said tablet or phone without opening said cover. It is clear that a large number of possible applications exist. What is important is that manipulation of magnets contained by said cover may be detected by a Hall sensor monitored according to the present invention, and this may be used, along with capacitive proximity measurements, or without, to activate or deactivate functions of a tablet or phone without opening said cover. Naturally, a user may configure the tablet or phone to determine which functions are thus controlled, according to the present invention.

In another related exemplary embodiment of the present invention, a charge transfer based integrated measurement circuit, which includes a plurality of Hall plate structures as disclosed and discussed above, may be used in a mobile electronic device, such as a tablet computer or a smart phone, in conjunction with at least one magnet in a cover for said device. The cover may have at least one aperture, through which a section of the display of said device may be viewed when the cover is closed. According to the present invention, said magnet or magnets have a specific orientation relative to the cover and device, and when the cover is closed, said integrated measurement circuit detects this orientation, and activates or deactivates a number of functions for controlling the display of the device. For example, a first cover with a first magnet orientation results in the display of said device being switched off when said first cover is closed. A second cover with a second magnet orientation may result in only a section of the display visible through said aperture being active when the cover is closed. A third cover with a third magnet orientation may result in yet another display function becoming active when the cover is dosed.

MEMS devices to measure acceleration are well represented in the prior art. A fair amount of such solutions utilize capacitive sensing of interleaving, multiple finger like structures to determine acceleration, wherein the structures are typically realized on silicon and move towards and from each other as the hosting device moves. The present invention teaches that such capacitive sensing based MEMS structures may be combined with a Hall plate sensor or sensors within a single integrated circuit device, be it single the or multi-die, and that both the MEMS structures and the Hall sensor may be monitored with a charge transfer measurement circuit as disclosed earlier. Further, according to the present invention, said Hall plate sensor or sensors may be used to detect the earth's magnetic field, and this detection may be used to determine the spatial orientation of said integrated circuit. A sensor arrangement which can measure magnetic field in three axes is included. The ability to monitor both acceleration and spatial orientation using a single IC which employs a charge transfer measurement technique, with all of the afore-mentioned advantages, may prove advantageous.

In yet another embodiment, a Hall plate sensor structure has the ability to sense changes in light incident on said plate in addition to magnetic field detection ability Charge transfer measurements may be used to monitor said plate outputs, or amplified or processed versions thereof, for both magnetic field detection and light sensing. According to the present invention, different biasing arrangements may be used to facilitate magnetic field monitoring or light intensity monitoring with said Hall plate structure. These biasing arrangements may be selectable, for example under control of a microchip or micro-controller, allowing the same sensor structure to be used to sense both magnetic field and light.

Essentially many different types of sensors may be linked to the charge transfer measurement system as disclosed, and obtain the advantage of a digitally controllable and easily programmable circuit compared to a prior art circuit that requires an analogue front end with various tuneable components and a number of discrete components.

The present invention teaches measurement of inductance values through the use of a charge transfer based measurement system. For example, according to the present invention, during a first phase, a target inductance may be connected to the one or other energy source to allow current though said inductor to increase in amplitude up to a certain value, where the rate of current increase may be dependent on the value of said target inductance and the voltage of said energy source. Thereafter, during a second phase, the target inductance may be disconnected from said energy source, with current through the inductance gradually decreasing by flowing via a so-called free-wheeling diode, as is known in the art. During the second phase, the current which flows via said free-wheeling diode may be used to facilitate transfer of charge to an accumulation capacitor. That is, according to the present invention, an accumulation capacitor may be charged with said free-wheeling current, or a derivative thereof. After a certain period, or when the free-wheeling current has reduced to a certain level, said first phase may be repeated, with the target inductance connected to said energy source again, allowing the current in the inductance to build up again. This may be followed by another second phase, and so forth, with said accumulation capacitor progressively charged up during each second phase with energy stored in the target inductance during the preceding first phase Said measurement system may keep track of the number of repetitions of said first and second phases, also known as charge transfer counts in the art. When the voltage on the accumulation capacitor reaches a certain value a comparator, which compares said voltage to a reference value, may trip, halting the process, whereby the number of charge transfer counts gives an indication of the value of said target inductance. This may be followed by the removal of charge from said accumulation capacitor, for example by short circuiting it, with a repetition of the above process. In an alternative embodiment, the process of repetitive first and second phases may be halted after a certain number of charge transfer counts, with the voltage on said accumulation capacitor providing an indication of said inductance.

Further, according to the present invention, any relevant technique known in the art of charge transfer based capacitive sensing may be used to improve the disclosed apparatus and method to measure the value of a target inductance. For example, current mirror structures may be used to generate a derivative of said free-wheeling current, allowing use of a much smaller accumulation capacitor than what would be the case if said capacitor is directly in series with said free-wheeling diode. Or compensation for parasitic inductances and capacitances may be performed, also with the aid of current mirror structures, as disclosed in U.S. Pat. No. 8,395,395 and U.S. Pat. No. 8,659,306, both of which are hereby incorporated in their entirety. Or said measurement system may determine a Long Term Average (LTA) of charge transfer counts for a specific target inductance, and use the LTA with digital filtering techniques to compensate for longer term or slow changes, such as, for example, due to temperature, component aging and so forth.

Naturally, in the preceding disclosure, the charge transfer measurement system for inductance measurement may be realised with an integrated circuit, comprising a single the or multiple dies within a single package. Further, the inductance measurement circuit disclosed may be included in multi-sensor integrated circuits as disclosed earlier. That is, according to the present invention, a single integrated circuit may be realised which may have the ability to use charge transfer based measurement of signal currents to facilitate measurement of capacitive proximity or touch, ambient light levels, PIR sensor currents, magnetic field strength or orientation and inductance, wherein the same charge transfer measurement circuit is used for all measurements.

In another related exemplary embodiment of the present invention, the freewheeling diode in the preceding disclosure on inductance measurement may be replaced by a transistor which is controlled by the measurement system. In other words, said transistor is turned on during said second phase, and allows the current of the target inductance to free-wheel, albeit with possibly smaller power losses than what is experience with a diode.

### BRIEF DESCRIPTION OF THE DRAWINGS

The invention is further described by way of examples with reference to the accompanying drawings in which:

FIG. 1 shows a block diagram of a prior art general measurement system.

FIG. 2 shows a block diagram of a charge transfer measurement system to obtain an average value from multiple measurements.

FIG. 3 shows a sampler block diagram.

FIG. 4 shows an alternative sampler block diagram.

FIG. 5 shows a current mirror.

FIG. 6 shows a block diagram of a charge transfer measurement system.

FIG. 7 shows a balanced Wheatstone bridge for sensing or modelling

FIG. 8 shows a balanced Wheatstone bridge for sensing or modelling with pre-amplification.

FIG. 9 shows a balanced Wheatstone bridge model with pre-amplification as applied to a Hall effect sensor in current mode.

FIG. 10 shows a model of a reverse biased photo diode.

FIG. 11 shows a circuit to connect a PIR sensor to a charge transfer measurement IC.

FIG. 12 shows an ASIC for measurement of magnetic field rotation using multiple Hall sensors and a charge transfer technique.

FIG. 13 shows a block diagram for an IC which monitors both a Hall plate structure or structures and a MEMS acceleration sensor structure with a charge transfer measurement system.

FIG. 14 shows a charge transfer measurement system used with a traditional smoke detector, allowing compensation to normalise when no smoke is present.

FIG. 15 shows an exemplary embodiment of the present invention wherein a Hall plate may be used to also measure light incident on it.

FIG. 16 shows an exemplary embodiment of a charge transfer based inductance measurement system.

FIG. 17 shows an exemplary embodiment of a charge transfer based inductance measurement system which utilizes a current minor to derive a charging current.

### DETAILED DESCRIPTION OF EMBODIMENTS

The following description of the appended drawings is presented to clarify the spirit and scope of the present invention, and not to limit it. It should be understood that these are exemplary embodiments, and a large number of alternative embodiments may exist which still fail within the scope of the claims for the present invention.

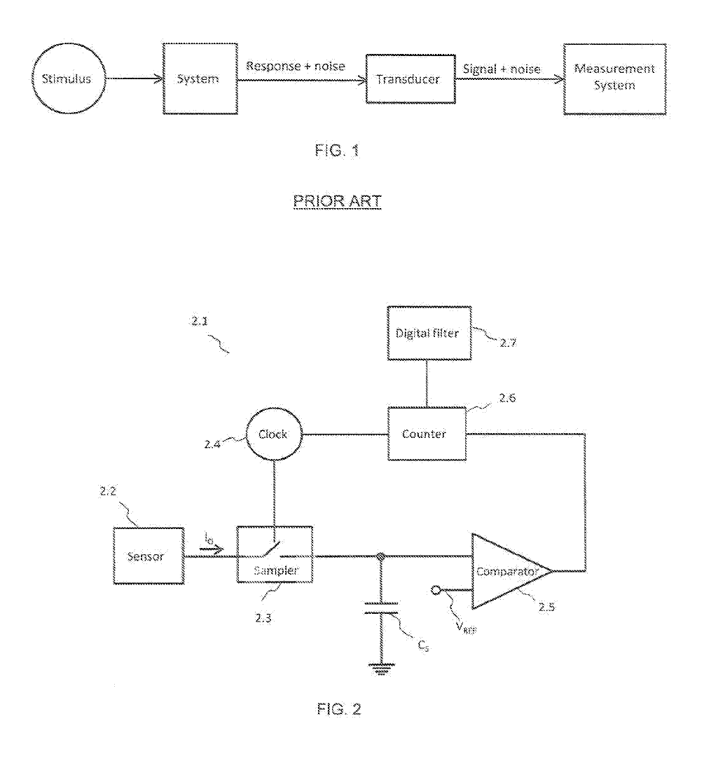

Refer to FIG. 2, which shows a block diagram of a charge transfer measurement system to obtain an average value from multiple measurements at (2.1). A sampler circuit (2.3) terminates the output from a sensor (2.2) in an appropriate impedance. Initially an accumulation capacitor (C_{S}) is discharged. Every time clock (2.4) goes high a sample (charge=Q_{O}) of the input current (Io) from sensor (2.2) is transferred to (C_{S}). When the voltage on (C_{S}) reaches the reference voltage. (V_{REF}), comparator (2.5) trips and stops counter (2.6). The average current I_{O}_{_}_{AVE} or charge Q_{AVE} sampled by the sampler circuit with each transfer may then be computed, as discussed during the Summary of Invention.

As shown in FIG. 2, a digital filter (2.7) may be utilized, wherein the system makes measurements on a regular basis and feed the value of Q_{AVE} into a digital filter which then calculates a long term average Q_{LTA}. This filter allows the system to track slow environmental changes like temperature drift, component aging and humidity and compensate for it. The signal change when the sensor detects a stimulus is Q_{Δ}=Q_{O}−Q_{LTA}. If a fixed limit was used instead of Q_{LTA} the system would be prone to false detections, or alternatively a big change in Qc would be required to eliminate false detections This is not always possible. The digital filter fulfils its function to allow the system to track slow environmental changes like temperature drift, component aging and humidity and compensate for it, however if it is found that the long term average drifts considerably the system can also determine a new value for Q_{b} by doing this a better detection sensitivity can be maintained.

FIG. 3 shows a block diagram for a sampler circuit as employed by the present invention at (3.1). The current from the sensor (I_{Z}) is terminated by an impedance (2). Current (I_{Z}) flows into the input of a current mirror structure (3.2), with a resultant current (I−I_{Z}). A background current (I_{S}) is subtracted from the sensor current via adder (3.3). The difference current (I_{Z}−I_{B}) goes to the gain block (3.4) with a resultant output current (G(I_{Z}-I_{B}). The system gain G can be larger than 1 or less than 1 depending on the application A clock (3.6) controls a switch (3.5). to facilitate providing an output of the sampler block at (3.7).

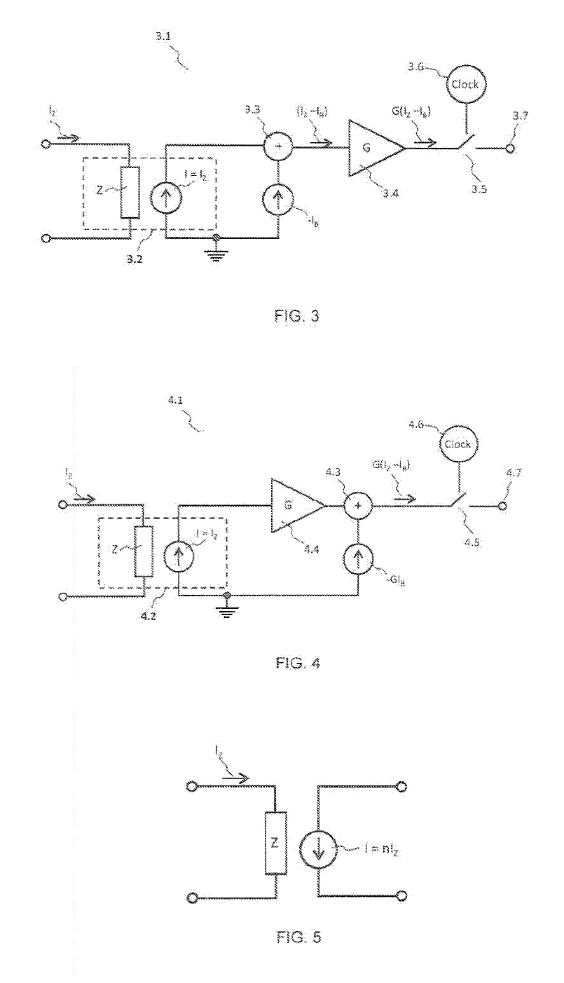

FIG. 4 shows a block diagram for an alternative sampler circuit. For certain applications it is better to do the summation after the gain block, as depicted in FIG. 4. as long as the gain block has sufficient dynamic range to handle the uncompensated input current. Reference numerals and characters for FIG. 4 have the same meaning as for FIG. 3, apart from the prescript “4”, e.g. (4.1) instead of (3.1), and will therefore not be elaborated

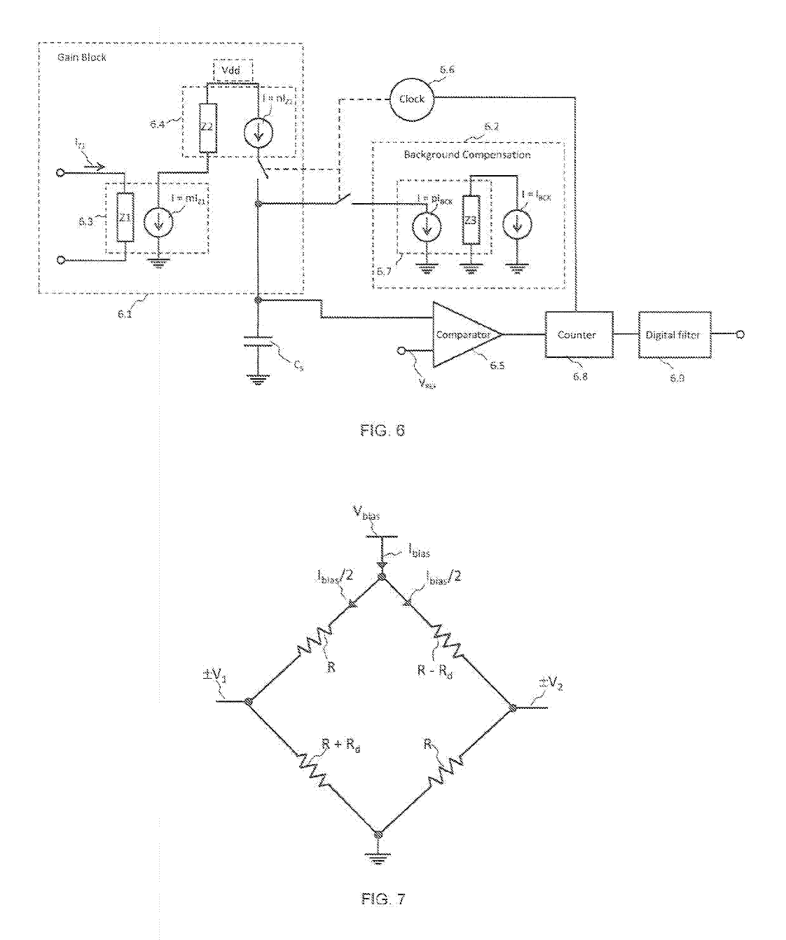

The main components of a charge transfer measurement system according to the present invention are shown in FIG. 6, namely an adjustable gain block (6.1). a background compensation block (6.2), a charge integrator (C_{S}) and peripheral electronics that include a comparator (6.5), a counter (6.8) and a digital filter (6.9). The gain block may be implemented with two adjustable current mirrors (6.3) and (6.4) allowing it to adjust the current gain up or down depending on the requirement of the specific application. The gain block (6.1) adds a packet of charge to the integrator or accumulation capacitor (C_{S}) with each pulse from clock (6.6).

The background compensation circuit can be implemented in many ways. One implementation, as shown in FIG. 6 at (6.2), is an adjustable current mirror (6.7) with an adjustable current source fed into the mirrors input port. With each clock (6.6) pulse the background compensation subtracts a packet of charge from the accumulation capacitor. Another method to implement the background compensation is a bank of switchable capacitors with a current mirror. During one half of the clock pulse the capacitors are charged up to the supply voltage, during the other half of the clock pulse, the capacitors are discharged through the current mirror removing a packet of charge from the accumulation capacitor. Switching capacitors in or out allows the system to adjust the amount of charge removed.

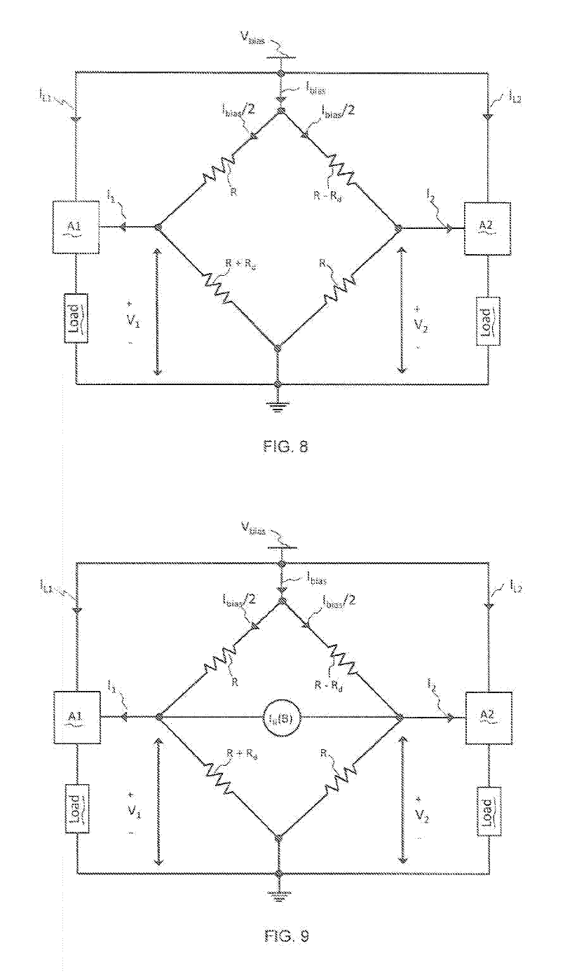

FIG. 8 depicts an improvement of a Wheatstone bridge model application, in that pre-amplification, represented by the two blocks marked (A1) and (A2), of the signal which can be either a current or a voltage being measured is performed. According to the present invention, a charge transfer measurement system is then implemented as the load, represented by the two blocks marked (Load) to the pre-amplification circuit. That is, the output of said pre-amplification circuit is used as input to the charge transfer measurement system as disclosed. The background compensation becomes a major advantage to eliminate the offset, allowing only the signal of interest to be measured.

FIG. 9 shows a Hall effect transducer in current mode (it may also be voltage mode) modelled using a Wheatstone bridge model. Currents (I1) and (I2) represents the Hall current that is directly proportional to the magnetic field B resulting from the Lorentz force acting upon the bias current (I_{bias}) flowing through the bridge. This signal is amplified with a gain A in blocks (A1) and (A2) and Is then measured and processed by the charge transfer measurement system as described above. In other words, the outputs of the two amplifiers (A1) and (A2) with gain A is used as input to the charge transfer measurement system as disclosed. According to the present invention, gain A in blocks (A1) and (A2) may be realised with a BJT structure inherently part of or integrated into the Hall sensor plate structure, using a typical CMOS fabrication process.

FIG. 10 presents use of charge transfer measurement based self-capacitance sensing IC to monitor a photodiode (10.1). Block (IQS 127) represents said IC with the self-capacitance of circuitry connected to pin marked (Cx) being measured. Photodiode (10.1) is modelled in its reverse biased position as a capacitor (10.2) (the junction capacitor) and a resistor (10.3) that varies according to the light intensity (10.5) that fails on it. The internal pn junction capacitance (10.2) may be supplemented with an external capacitor (10.4) in order to achieve the appropriate values. When more light falls onto the photodiode. the value of resistor (10.3) becomes lower in Ohms to the effect that some charge stored in the capacitor. or combined capacitors, is leaked to ground. The change in light (10.5) falling on the photodiode (10.1) thus has a direct impact on the charge transfer measurement value.

In FIG. 11 an exemplary embodiment is shown using a PIR sensor (11.1) which is a three terminal device, comprising typically a dual sensor connected to a FET that is enclosed in a metal housing with a translucent lens. In this embodiment the drain pin (D) of said PIR sensor is connected through a blocking diode (11.3) and a resistor (R_{TX}) to the transmit line (Tx) of a charge transfer based projected capacitive measurement device (not shown), with the source pin (S) of the sensor connected to the receiver line (C_{X}) as shown. Using such an embodiment, signal deviation may be measured with high resolution when different objects projects radiation onto the sensing elements of the PIR sensor. A capacitor (11.2) may be connected to the (Cx) line, to improve measurement stability, however, this is not taught as a limit, and the invention may be practised without said capacitor.

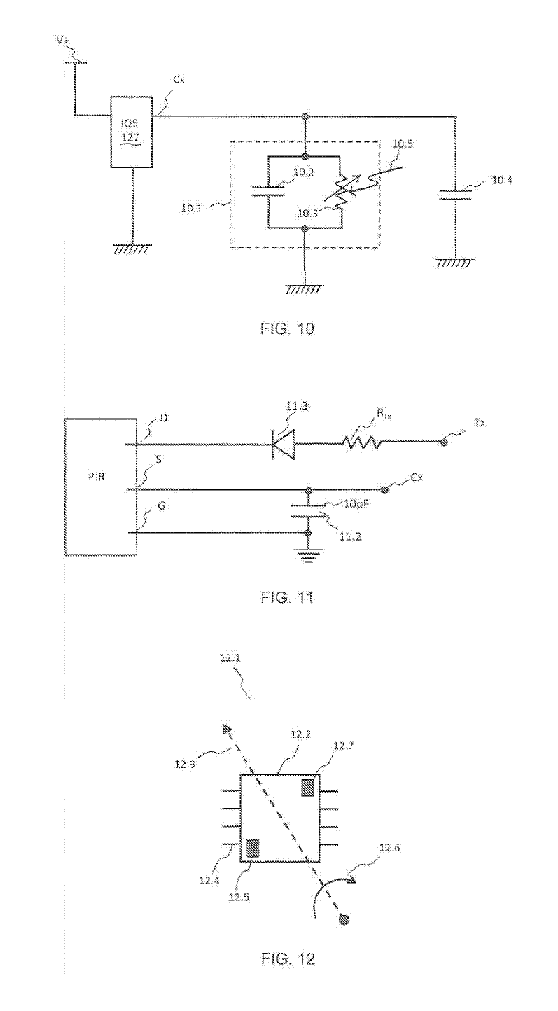

FIG. 12 shows an exemplary embodiment that illustrates the above at (12.1). An ASIC (12.2) contains two Hall sensors (12.6) and (12.7), with distinct locations within the ASIC A magnetic field (12.3) is incident on the ASIC, and rotates, as shown by (12.6) Said ASIC also comprises charge transfer measurement and processing circuitry, riot shown, to monitor said Hall sensors according to the preceding disclosure. Supply voltages, analog inputs and outputs and digital inputs and outputs are facilitated by pins of the ASIC package, as shown by (12.4). As magnetic field (12.3) rotates, Hall sensors (12.5) and (12.7) should experience varying levels of magnetic field incident on them, with corresponding outputs in the charge transfer measurement circuitry used to monitor them. As disclosed, by analysing said outputs in terms of time and amplitude, the rotation of said field may be determined. Further. Hall sensors (12.5) and (12.7) need not be oriented in the same way, but may be placed at any relevant angle to each other to facilitate measurement of the rotation of magnetic field (12.3).

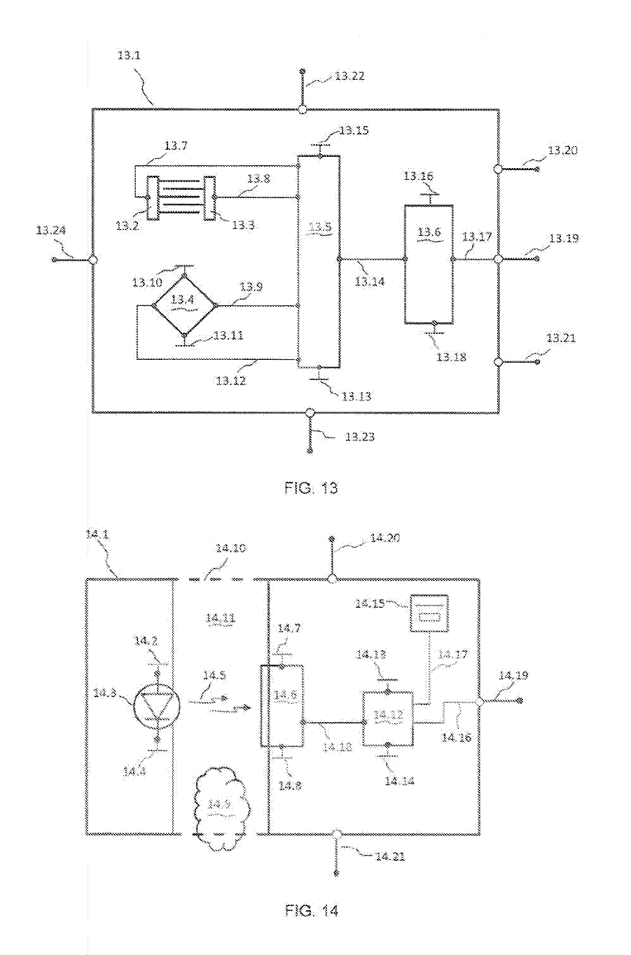

An integrated circuit or device (13,1) which comprises both a MEMS acceleration sensor structure (13.2) and (13.3), and a Hall plate structure (13.4), and wherein both structures are monitored using a charge transfer measurement circuit (13.6) as disclosed, is presented in exemplary manner in FIG. 13. In the embodiment shown, said MEMS acceleration structure sensor consists of (13.2) and (13.3), which may be finger like conductive structures which are interleaved, as is known in the art. When the device accelerates, the finger like structures moves closer or further from each other. This may change the capacitance measured between lines (13.7) and (13.8). According to the present invention, a multiplexing circuit (13.5) may be used to connect these lines to a charge transfer measurement circuit (13.8), as disclosed earlier, using interconnect or interconnections (13.14). Circuit (13.8) may then utilize charge transfer measurement techniques as disclosed and discussed earlier to measure said change in capacitance, from which said acceleration may be deduced. Multiplexing circuit (13.5) may be biased via interconnections (13.15) and (13.13) from a power source (not shown). It is to be appreciated that multiplexing circuit (13.5) is not required to practise the teachings of the present invention, and that lines (13.7) and (13.8) may be connected directly to charge transfer measurement circuit (13.6).

In addition to said MEMS structure, integrated circuit or device (13.1) also contains a Hall sense plate structure (13.4), biased in the appropriate manner, as is known in the art of Hall sensors, via connections (13.10) and (13.11) from a supply (not shown). Outputs (13.9) and (13.12) of Hall structure (13.4) may be connected to multiplexing circuit (13.5), allowing the use of charge transfer measurement circuit (13.6) to monitor the Hall sense plate structure via interconnect or interconnections (13.14). Of course, as above, multiplexing circuit (13.5) is not exclusively required to practise the teachings of the present invention, irrespective of whether the MEMS structure or the Hall sense plate structure is being monitored, charge transfer measurement circuit (13.6) may provide an output or outputs via interconnect or interconnects (13.17), wherein said outputs may be in digital or analog format. The output or outputs of the charge transfer measurement circuit may be provided at pin or pins (13.19) of the integrated circuit (13.1), which may also employ a number of other pins (13.20)-(13.24), for example supply pins, control pins, communication pins and so forth.

With regards to the exemplary embodiment of FIG. 13, it should be noted that the present invention should not be limited to acceleration sensor MEMS structures only, but that any relevant MEMS structure which may be combined with a Hall sense plate structure within an integrated circuit and monitored with a charge transfer measurement circuit as disclosed, may fall within the claims of the present invention.

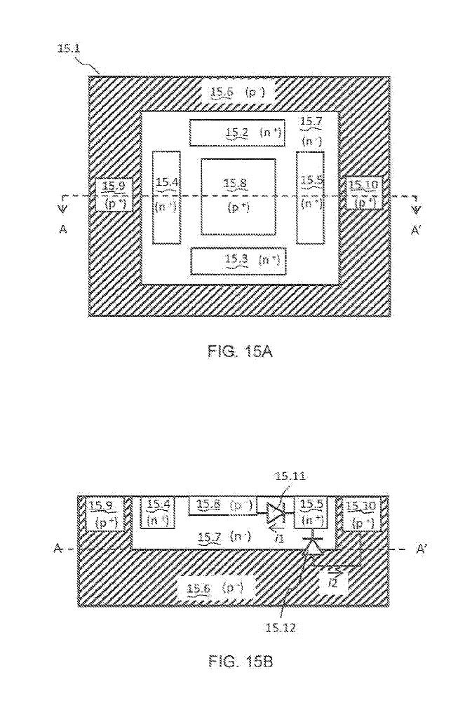

FIG. 14 depicts a smoke detector (14.1) according to the present invention in exemplary manner. Said detector has perforations (14.10) in its housing, allowing smoke (14.9) to move into a channel or guide (14.11). An light emitting device (14.3), for example an LED, and a light detector (14.6), for example a photodiode or photo-transistor, are located within line of sight of each other, allowing emitted light (14.5) to directly fall onto detector (14.6) Emitting device (14.3) may be biased from a power source (not shown) via interconnections (14.2) and (14.4), and correspondingly, light detector (14.8) may be biased via interconnections (14.7) and (14.8). When smoke (14.9) moves into channel (14.11) in between said emitter (14.3) and light detector (14.6), the output signal of the light detector at interconnect (14.18), for example a current, should change correspondingly. According to the present invention, said current, or other signal, may be monitored with a charge transfer measurement circuit (14.12) as disclosed. Said charge transfer measurement circuit is supplied from a power source (not shown) via interconnects (14.13) and (14.14). Background compensation as disclosed may be used by charge transfer measurement circuit (14.12) to remove an amount of current equal to that present in (14.18) when no smoke impedes transmission of light (14.5), from all subsequent measurements. Naturally, the signal used as input to circuit (14.12) need not be a current, but may be a voltage as well. Further, long term averaging techniques as disclosed and discussed earlier may be used by circuit (14.12) to compensate for slow changes in output due to environmental parameters.

In the example presented by FIG. 14. charge transfer measurement circuit (14.12) may comprise sufficient intelligence to detect when the output of light detector (14.6) crosses a predetermined threshold, i.e. when more than an allowable amount of smoke is present between emitter (14.3) and light detector (14.6), and to provide an indication of such detection via interconnect (14.18) and pin (14.19). Circuit (14.12) may also have the ability to drive a buzzer or speaker (14.15) directly or indirectly upon said detection. Smoke detector (14.1) may be powered via pins or connections (14.20) and (14.21) by an external power source (not shown), or it may be powered internally by a battery (not shown).

In FIG. 15A, a top view of a Hall sense plate structure, as is known in the prior art, is presented at (15.1), with an accompanying sectional view along AA⁺ presented in FIG. 15B at (15.11). The Hall plate comprises an n-well or section of n⁻ doped semiconductor material (15.7) located within a larger piece of p doped semiconductor material (15.6). The biasing for the Hall plate is applied to two contacts (15.2) and (15.3), both consisting of n⁺ doped semiconductor material. To measure the Hall voltage, or Hall currents that occur due to the Hall effect, two additional contacts (15.4) and (15.5) are realised on said n-well (15.7), wherein both contacts consist of n⁺ doped semiconductor material. The aforementioned is well known in the art of Hall sensors. In addition, a section of p⁺ doped semiconductor (15.8) is often realized on top of the n-well (15.7) to reduce the effective thickness of said n-well, with section (15.8) floating. Further, contacts comprising p⁺ doped semiconductor material, such as (15.9) and (15.10) are often realised on the larger section of p⁻ material for biasing purposes.

According to the present invention, such a structure may also be used to detect light incident on the Hall sense plate structure. As known in the arts of semiconductors, diodes are realized wherever a pn-junction exits. Therefore, a diode (15.11) is realized between p-doped section (15.8) and n-well (15.7). and another diode (15.12) is realized between p-doped material (15.8) and n-well (15.7). Diode (15.11) may be biased through a contact on section (15.8) (anode) and contact (15.5) (cathode), and diode (15.12) may be biased through contacts (15.10) (anode) and (15.5) (cathode). The diodes present in the structure depicted by FIG. 15A and FIG. 15B are naturally not just limited to the two under discussion.

If diode (15.11) is used as a photodiode and reverse biased, a current i1 which is dependent on the amount of light incident on the structure will flow, as illustrated. Similarly, if diode (5.12) is used as photodiode, and reverse biased, a current i2 which is dependent on the amount of light incident on the structure will flow. Different wavelengths of light will penetrate the structure to different depths. This may allow a structure as in FIG. 15 to sense lights of various wavelengths, and to discern between wavelengths. For example, diode (5.11) may be used to sense shorter wavelengths, and diode (5.12) to sense longer wavelengths.

Therefore, according to the present invention, an exemplary structure as depicted at in FIG. 15A may be used to measure both the magnetic field and light incident on said structure, dependent on the biasing applied to contacts (15.2) to (15.5) and (15.8) to (15.10), and wherein said measurements are performed using a charge transfer circuit as disclosed and discussed earlier. It should be noted that the present invention is not limited to the structure depicted in FIG. 15, but includes any semiconductor structure where the Hall effect is used to sense a magnetic field incident on said structure, and wherein alternative biasing of contacts contained by the structure allows pn-diodes realized by said structure to be used as photodiodes, thus enabling sensing of light incident on said structure.

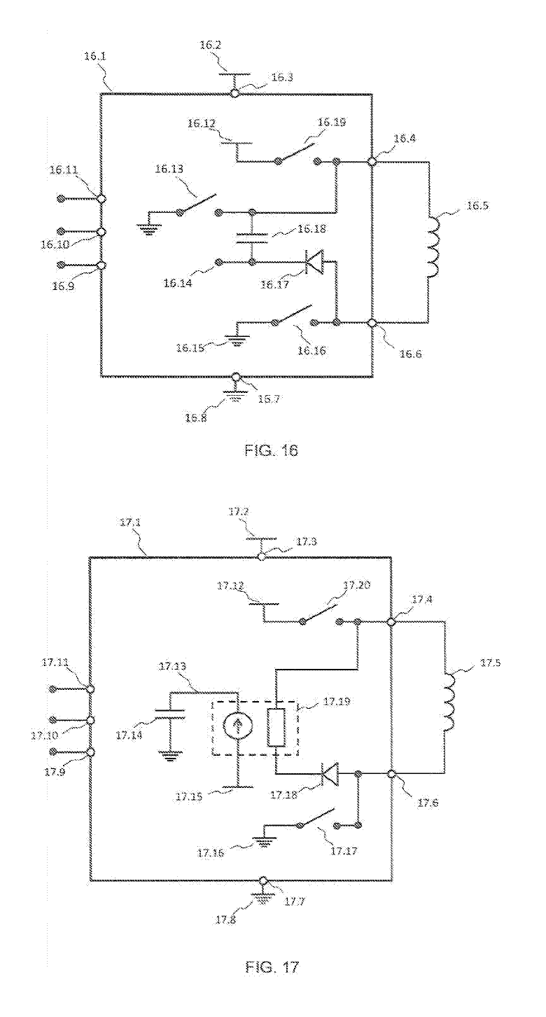

Yet another exemplary embodiment of the present invention Is illustrated by FIG. 16. where a target inductance (16.5) may be measured with a charge transfer based measurement system (16.1). The system may receive electrical power via terminals (16.3) and (16.7), connected to a voltage bus (16.2) and ground (16.8) respectively. Target inductance (16.5) may be connected to the system via terminals (16.4) and (16.6). The system may have other terminals, such as (16.9), (16.10) and (16.11), which may be used for communication, control or other functions. During a first phase of system operation, inductance (16.5) may be connected to a system internal voltage bus, or current source (not shown), (16.12) and to ground (16.15) by closure of switches (16.19) and (16.16). This should result in current flowing through inductance (16.5) and increasing according to the voltage present across said inductance. During a second phase, when switches (16.19) and (16.16) are opened, current through said inductance should free-wheel via diode (16.17) and capacitor (16.18), which should result in an increasing amount of charge stored in said capacitor. The free-wheeling current should gradually decrease as more energy is stored in capacitor (16.18) in the form of transferred charge, until the magnetic energy remaining in inductance (16.5) is not sufficient to ensure further capacitor charging, or if switches (16.19) and (16.16) close again to start a new first phase, which may allow current in said inductance to increase. Dependent on the relative sizes of inductance (16.5) and capacitor (16.18), and the amplitudes of the relevant voltage and currents, a number of repetitions of said first and second phases of charge transfer may be required before capacitor (16.8) is charged to a predetermined voltage. The voltage of capacitor (16.18) may be measured relative to ground by closing switch (16.13) while switches (16.19) and (16.16) are open, although the present invention is certainly not limited in this regard. Measurement system (16.1) may keep track of the number of charge transfers, or charge transfer counts, required to fill capacitor (16.18) to a predetermined voltage, or may measure a time count to achieve said capacitor voltage. Alternatively, measurement system (16.1) may halt the measurement process after a number of charge transfers, and measure the voltage across capacitor (16.18). In either case, the transfer counts, time counts or capacitor voltage may be used by said system to determine the inductance value of target inductance (16.5).

Another exemplary embodiment closely related to the above is presented in FIG. 17. Reference numerals for FIG. 17 are mainly the same as for FIG. 16, therefore, for brevity's sake, only those references which differ will be discussed. Charge transfer based inductance measurement system (17.1) includes use of a current mirror structure (17.19) which facilitates use of a derivative of the free-wheeling current through diode (17.18) to charge capacitor (17.14) via interconnect (17.13) when switches (17.17) and (17.20) are open during a second phase, wherein first and second phases are as disclosed earlier. Current mirror (17.19) may be fed from system internal voltage bus (17.15). The operation of the apparatus in FIG. 17 is similar to that described for FIG. 16, where said system tracks the number of charge transfer counts, or time counts, or a voltage on capacitor (17.14) after a predetermined period. Naturally, the present invention is not limited to use of a single current mirror to increase or reduce the amount of current used to charge an accumulation capacitor such as (17.14), based on said free-wheeling current, but may utilize any number of current mirror or other relevant structures to implement said increase or reduction.

1-24. (canceled)

25. An integrated circuit characterised by the use of a charge transfer measurement system within said integrated circuit to convert a first signal current into a digital measurement value, wherein said system comprise a clock source, an accumulation capacitor and current mirrors, wherein charge transferred is accumulated in said accumulation capacitor during said conversion, wherein the first signal current flow due to a magnetic field incident on a plurality of Hall plate sensor structures, wherein said structures are located within said integrated circuit, wherein said integrated circuit comprise circuitry to determine rotation of said magnetic field from said digital measurement values and wherein said integrated circuit further converts additional signal currents into digital measurement values through the use of said charge transfer measurement system, with the additional signal currents flowing due to one of the following:
light incident on at least one reverse biased photodiode, wherein said photodiode is located within said integrated circuit or located external to the integrated circuit and connected to it; and
a change in a capacitance, wherein said capacitance is located within said integrated circuit or located external to the integrated circuit and connected to it.

26. The integrated circuit of claim 25, wherein said integrated circuit maintains long term averages of said digital measurement values, and utilizes digital filtering to compensate for drifts in said average.

27. The integrated circuit of claim 26, wherein said system subtracts a value representative of a background current from said signal current.

28. The integrated circuit of claim 26, wherein said system applies a gain of more or less than one to said signal current.

29. The integrated circuit of claim 28, wherein said current mirror structures are used to facilitate said subtraction.

30. The integrated circuit of claim 29, wherein said current mirror structures are used to facilitate said gain application.

31. The integrated circuit of claim 25 used in a tablet computer or a smart phone and in conjunction with at least one magnet, wherein said magnet is located within a cover for said computer or phone and provides said incident magnetic field, and wherein a user can manipulate said magnet when the cover is closed, wherein said manipulation cause said rotation of the incident magnetic field, allowing said integrated circuit to detect said manipulation, and wherein said detection results in activation or deactivation of functions by the computer or phone.

32. The integrated circuit of claim 31, wherein the detection of magnet manipulation by said integrated circuit results in one or more of the following functions being activated or deactivated by the computer or phone:
a low power sleep mode which continues to download email;
a silent mode;
a cover opening alarm, which requires a specific sequence of magnet manipulation to deactivate it;
a sound recording function; and
an emergency notification function that sends an emergency message or GPS coordinates of the computer or phone to a pre-selected recipient.

33. The integrated circuit of claim 31, wherein said magnet has a specific orientation relative to said cover and the computer or smart phone, with apertures located within said cover, wherein said apertures facilitates viewing a display section of said computer or phone when said cover is closed, and wherein said manipulation changes said specific orientation, wherein the integrated circuit detects the change in magnet orientation and correspondingly cause activation or deactivation of a function or mode for said display or display section by the computer or phone.

34. The integrated circuit of claim 25, wherein at least one of said Hall plate structures comprises a plurality of biasing contacts, and wherein a first biasing arrangement of said contacts facilitates magnetic field sensing, a second biasing arrangement facilitates sensing light of a first wavelength and a third biasing arrangement facilitates sensing light of a second wavelength, and wherein said second and third biasing arrangements cause diodes present in said Hall plate structure to be reverse biased.

35. The integrated circuit device of claim 25, wherein at least one of said Hall plate structures facilitates measurement of the earth's magnetic field, to facilitate a determination of a spatial orientation from said measurement.

36. The integrated circuit device of claim 25, wherein at least one of said Hall plate structures facilitates measurement of magnetic field strength in along three axes.

37. The integrated circuit of claim 25, wherein said change in capacitance is due to a user touch on, or proximity to, at least one self-capacitance or mutual capacitance touch sensor structure.

38. The integrated circuit of claim 25, wherein said change in capacitance is due to an acceleration of at least one capacitive MEMS accelerometer sensor, wherein said sensor is located within said integrated circuit or connected to said integrated circuit.
